(19) United States
(12) Patent Application Publication
(10) Pub. No.: US 2026/0190985 A1
(43) Pub. Date: Jul. 2, 2026

(54) SEMICONDUCTOR ELEMENT AND SEMICONDUCTOR APPARATUS

(71) Applicant: SONY SEMICONDUCTOR SOLUTIONS CORPORATION, Kanagawa (JP)

(72) Inventors: Kazuyuki TOMIDA, Kanagawa (JP); Shinichi MIYAKE, Kanagawa (JP); Katsuhiko HANZAWA, Kanagawa (JP)

(73) Assignee: SONY SEMICONDUCTOR SOLUTIONS CORPORATION, Kanagawa (JP)

(21) Appl. No.: 18/728,043

(22) PCT Filed: Dec. 28, 2022
(86) PCT No.: PCT/JP2022/048575

§ 371 Date: Jul. 10, 2024

(30) Foreign Application Priority Data
Jan. 17, 2022 (JP) 2022-005360

(51) Int. Cl. H10W 20/40; H10W 90/00

(52) U.S. Cl. CPC H10W 20/496; H10W 90/792

(57) ABSTRACT

A manufacturing process is simplified. A semiconductor element includes: a first wiring region of a first semiconductor substrate; a second wiring region of a second semiconductor substrate; a first pad embedded in a surface of the first wiring region; a second pad embedded in a surface of the second wiring region and at a position overlapping the first pad when the first wiring region and the second wiring region are bonded; a capacitive element disposed on any one of the first pad and the second pad; and a capacitive element connection pad embedded in the first wiring region and connected to the second pad when the first wiring region and the second wiring region are bonded.

### FIELD

The present disclosure relates to a semiconductor element and a semiconductor apparatus.

### BACKGROUND

In order to downsize a element, a semiconductor element configured by bonding a plurality of semiconductor substrates is used. The bonding of the semiconductor substrates can be performed by bonding wiring regions disposed on the semiconductor substrates to each other. Specifically, by activating surfaces of insulating layers of the wiring regions and performing thermal pressure welding, the insulating layers of the wiring regions can be bonded to each other. In addition, exchange of electrical signals between the bonded wiring regions can be performed via pads disposed on bonding surfaces of the respective wiring regions. The pad is a region where metal such as an electrode is disposed. The pads aligned with each other are disposed in the respective wiring regions, and these pads can be bonded at the time of bonding the insulating layers described above.

In such a semiconductor element, a semiconductor apparatus in which a metal insulator metal (MIM) capacitor is formed in a via plug disposed on a surface of one wiring region has been proposed (see, for example, Patent Literature 1). This capacitor is bonded to the pad disposed on the surface of the other wiring region.

### CITATION LIST

### Patent Literature

Patent Literature 1: JP 2019-114595 A

### SUMMARY

### Technical Problem

However, in the conventional technique described above, since the capacitor made of MIM is formed in the narrow via plug, there is a problem that it is difficult to manufacture the capacitor.

Therefore, the present disclosure proposes a semiconductor element and a semiconductor apparatus having an easily manufacturable MIM capacitor.

### Solution to Problem

A semiconductor element according to the present disclosure includes: a first semiconductor substrate; a second semiconductor substrate; a first wiring region disposed adjacent to the first semiconductor substrate; a second wiring region disposed adjacent to the second semiconductor substrate and having a surface bonded to a surface of the first wiring region; a first pad embedded in the surface of the first wiring region; a second pad embedded in the surface of the second wiring region and disposed at a position overlapping the first pad in plan view when the surface of the first wiring region and the surface of the second wiring region are bonded; a capacitive element configured by sequentially stacking a first electrode, a dielectric layer, and a second electrode disposed on any one of the first pad and the second pad; and a capacitive element connection pad that is a pad embedded in the surface of the first wiring region and connected to the second pad when the surface of the first wiring region and the surface of the second wiring region are bonded.

A semiconductor apparatus according to the present disclosure includes: a first semiconductor substrate; a second semiconductor substrate; a first wiring region disposed adjacent to the first semiconductor substrate; a second wiring region disposed adjacent to the second semiconductor substrate and having a surface bonded to a surface of the first wiring region; a first pad embedded in the surface of the first wiring region; a second pad embedded in the surface of the second wiring region and disposed at a position overlapping the first pad in plan view when the surface of the first wiring region and the surface of the second wiring region are bonded; a capacitive element configured by sequentially stacking a first electrode, a dielectric layer, and a second electrode disposed on any one of the first pad and the second pad; a capacitive element connection pad that is a pad embedded in the surface of the first wiring region and connected to the second pad when the surface of the first wiring region and the surface of the second wiring region are bonded; a first electronic circuit connected to the first pad via a wiring disposed in the first wiring region; and a second electronic circuit connected to the capacitive element connection pad via a wiring disposed in the first wiring region.

### BRIEF DESCRIPTION OF DRAWINGS

FIG. 1 is a diagram illustrating a configuration example of a semiconductor element according to an embodiment of the present disclosure.

FIG. 2 is a diagram illustrating a configuration example of a semiconductor element according to a first embodiment of the present disclosure.

FIG. 3A is a diagram illustrating a configuration example of a capacitive element according to the first embodiment of the present disclosure.

FIG. 3B is a diagram illustrating a configuration example of the capacitive element according to the first embodiment of the present disclosure.

FIG. 4A is a diagram illustrating an example of a method for manufacturing the semiconductor element according to the first embodiment of the present disclosure.

FIG. 4B is a diagram illustrating the example of the method for manufacturing the semiconductor element according to the first embodiment of the present disclosure.

FIG. 4C is a diagram illustrating the example of the method for manufacturing the semiconductor element according to the first embodiment of the present disclosure.

FIG. 4D is a diagram illustrating the example of the method for manufacturing the semiconductor element according to the first embodiment of the present disclosure.

FIG. 4E is a diagram illustrating the example of the method for manufacturing the semiconductor element according to the first embodiment of the present disclosure.

FIG. 4F is a diagram illustrating the example of the method for manufacturing the semiconductor element according to the first embodiment of the present disclosure.

FIG. 4G is a diagram illustrating the example of the method for manufacturing the semiconductor element according to the first embodiment of the present disclosure.

FIG. 4H is a diagram illustrating the example of the method for manufacturing the semiconductor element according to the first embodiment of the present disclosure.

FIG. 5 is a diagram illustrating a configuration example of a capacitive element according to a second embodiment of the present disclosure.

FIG. 6A is a diagram illustrating an example of a method for manufacturing a semiconductor element according to the first embodiment of the present disclosure.

FIG. 6B is a diagram illustrating the example of the method for manufacturing the semiconductor element according to the first embodiment of the present disclosure.

FIG. 6C is a diagram illustrating the example of the method for manufacturing the semiconductor element according to the first embodiment of the present disclosure.

FIG. 7A is a diagram illustrating a configuration example of a capacitive element according to a third embodiment of the present disclosure.

FIG. 7B is a diagram illustrating a configuration example of the capacitive element according to the third embodiment of the present disclosure.

FIG. 8A is a diagram illustrating another configuration example of the capacitive element according to the third embodiment of the present disclosure.

FIG. 8B is a diagram illustrating another configuration example of the capacitive element according to the third embodiment of the present disclosure.

FIG. 9A is a diagram illustrating a configuration example of a capacitive element according to a modified example of the embodiment of the present disclosure.

FIG. 9B is a diagram illustrating a configuration example of a capacitive element according to a modified example of the embodiment of the present disclosure.

FIG. 10 is a block diagram illustrating a configuration example of an imaging element to which the technology according to the present disclosure can be applied.

FIG. 11 is a diagram illustrating a configuration example of a pixel to which the technology according to the present disclosure can be applied.

FIG. 12 is a diagram illustrating a configuration example of a current-voltage conversion circuit and a differentiating circuit to which the technology according to the present disclosure can be applied.

FIG. 13 is a diagram illustrating a configuration example of a pixel array unit to which the technology according to the present disclosure can be applied.

### DESCRIPTION OF EMBODIMENTS

Hereinafter, embodiments of the present disclosure will be described in detail with reference to the drawings. The description will be given in the following order. Note that in the following embodiments, the same parts are denoted by the same reference numerals, and redundant description will be omitted.
1. First Embodiment
2. Second Embodiment
3. Third Embodiment
4. Modified Example
5. Application Example

### 1. FIRST EMBODIMENT

### [Configuration of Semiconductor Element]

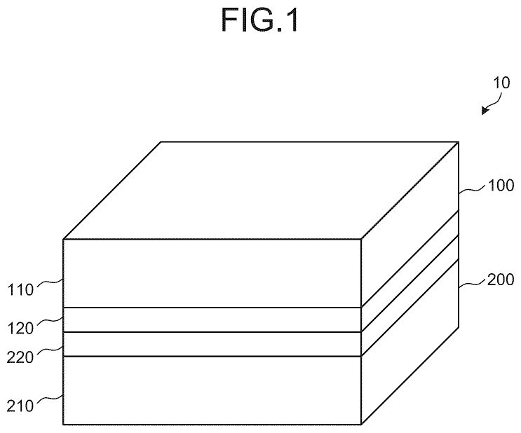

FIG. 1 is a diagram illustrating a configuration example of a semiconductor element according to an embodiment of the present disclosure. The drawing is a diagram illustrating a configuration example of a semiconductor element 10. The semiconductor element 10 is a semiconductor element configured by stacking a semiconductor chip 100 and a semiconductor chip 200. The semiconductor chip 100 in the drawing includes a semiconductor substrate 110 and a wiring region 120. In addition, the semiconductor chip 200 in the drawing includes a semiconductor substrate 210 and a wiring region 220. As illustrated in the drawing, the semiconductor chip 100 and the semiconductor chip 200 are stacked by bonding the respective wiring regions.

As described above, since the semiconductor chips 100 and 200 are stacked in the semiconductor element 10, the area of a chip surface can be reduced. In addition, circuits having different properties can be disposed in the semiconductor chips 100 and 200. For example, a logic circuit that handles digital signals may be disposed in the semiconductor chip 100, and a circuit that handles analog signals may be disposed in the semiconductor chip 200. In this case, the semiconductor chips 100 and 200 can be manufactured by applying a manufacturing process suitable for each circuit.

### [Configuration of Cross-Section of Semiconductor Element]

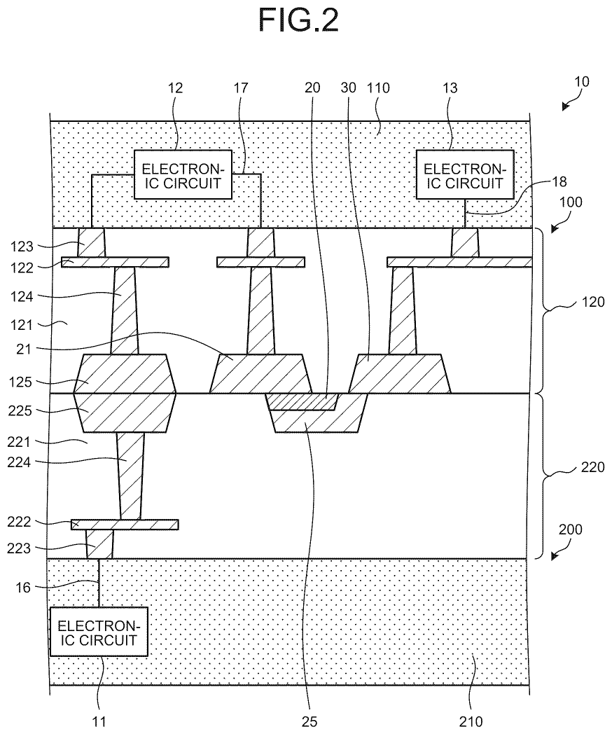

FIG. 2 is a diagram illustrating a configuration example of the semiconductor element according to the first embodiment of the present disclosure. The drawing is a cross-sectional view illustrating the configuration example of the semiconductor element 10. As described above, the semiconductor chip 100 includes the semiconductor substrate 110 and the wiring region 120, and the semiconductor chip 200 includes the semiconductor substrate 210 and the wiring region 220.

The semiconductor substrate 110 is a semiconductor substrate in which a diffusion layer of a semiconductor element is formed. As the semiconductor substrate 110, for example, a substrate made of silicon (Si) can be used.

The wiring region 120 is a region that is disposed on a front-surface side of the semiconductor substrate 110 and in which a wiring of an element formed in the semiconductor substrate 110 is formed. The wiring region 120 includes an insulating layer 121 and a wiring 122. The insulating layer 121 insulates the semiconductor substrate 110 and the wiring 122. The insulating layer 121 can be made of, for example, silicon oxide (SiO₂). The wiring 122 transmits an electric signal or the like to the element formed in the semiconductor substrate 110. The wiring 122 can be made of metal such as copper (Cu), for example.

The insulating layer 121 and the wiring 122 can be configured in multiple layers. In this case, the wirings 122 disposed in different layers can be connected by a via plug 124. The via plug 124 in the drawing connects a pad 125 to be described later and the wiring 122. The via plug 124 is a columnar conductor and can be made of metal such as Cu. In addition, a contact plug 123 is disposed between the wiring 122 and the semiconductor substrate 110. The contact plug 123 is also a columnar conductor and can be made of metal such as tungsten (W).

The semiconductor substrate 210 is a semiconductor substrate similar to the semiconductor substrate 110. The wiring region 220 is disposed on a front-surface side of the semiconductor substrate 210 and includes an insulating layer 221, a wiring 222, a contact plug 223, and a via plug 224.

The pad 125 is disposed on a surface of the wiring region 120. In addition, a pad 225 is disposed on a surface of the wiring region 220. These pads 125 and 225 are pads that are bonded and electrically connected when the wiring regions 120 and 220 are bonded together. Similarly to the via plugs 124 and 224, the pads 125 and 225 can be made of Cu. Hereinafter, such connection by the pads 125 and 225 is referred to as pad-to-pad connection. Note that in the wiring region 120, a pad 21 and a capacitive element connection pad 30 to be described later are disposed. The via plug 124 is connected to each of the pad 21 and the capacitive element connection pad 30. In addition, a pad 25 to be described later is disposed in the wiring region 220.

A plurality of electronic circuits can be disposed in the semiconductor element 10. The semiconductor element 10 in the drawing illustrates an example in which electronic circuits 11 to 13 are disposed. The electronic circuit 11 is disposed in the semiconductor substrate 210 of the semiconductor chip 200 in the drawing. In addition, the electronic circuit 12 and the electronic circuit 13 are disposed in the semiconductor substrate 110 of the semiconductor chip 100.

In addition, the semiconductor element 10 in the drawing further includes a capacitive element 20. The capacitive element 20 is also referred to as a capacitor, and is an element in which a dielectric is disposed between two conductors. The capacitive element 20 in the drawing is embedded in a recess formed in the pad 25. When the wiring region 120 and the wiring region 220 are bonded, the pad 21 is connected to the capacitive element 20. That is, one conductor of the capacitive element 20 and the pad 25 are connected, and the other conductor of the capacitive element 20 and the pad 21 are connected. In addition, by this bonding, a region of a surface of the pad 25 on which the capacitive element 20 is not disposed is connected to the capacitive element connection pad 30. The capacitive element 20 is connected between the electronic circuit 12 and the electronic circuit 13.

The electronic circuit 11 and the electronic circuit 12 are connected by a signal line 16. In the drawing, the signal line 16 includes the contact plug 223, the wiring 222, the via plug 224, the pad 225, the pad 125, the via plug 124, the wiring 122, and the contact plug 123.

In addition, the electronic circuit 12 and the capacitive element 20 are connected by a signal line 17. In the drawing, the signal line 17 includes the contact plug 123, the wiring 122, the via plug 124, and the pad 21. In addition, the capacitive element 20 and the electronic circuit 13 are connected by a signal line 18. In the drawing, the signal line 18 includes the pad 25, the capacitive element connection pad 30, the via plug 124, the wiring 122, and the contact plug 123.

Note that the semiconductor substrate 110 is an example of a first semiconductor substrate described in the claims. The semiconductor substrate 210 is an example of a second semiconductor substrate described in the claims. The wiring region 120 is an example of a first wiring region described in the claims. The wiring region 220 is an example of a second wiring region described in the claims.

### [Configuration of Capacitive Element]

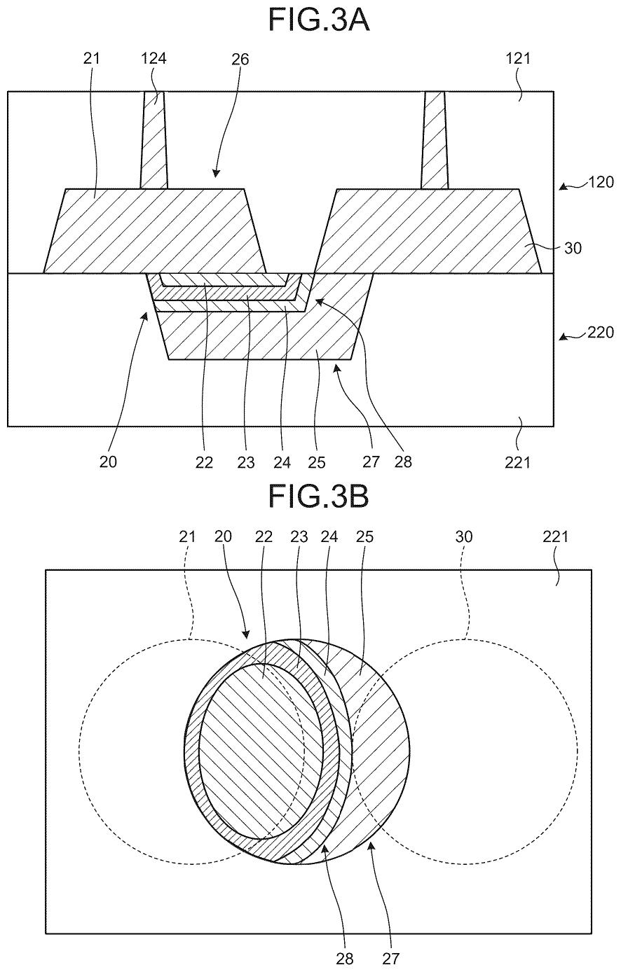

FIGS. 3A and 3B are diagrams illustrating a configuration example of the capacitive element according to the first embodiment of the present disclosure. FIG. 3A is a cross-sectional view illustrating a configuration example of the capacitive element 20. As described above, the capacitive element 20 in the drawing is disposed between the pad 21 and the pad 25. The capacitive element 20 is configured by sequentially stacking a first electrode 22, a dielectric layer 23, and a second electrode 24. In this manner, the capacitive element 20 constitutes an MIM capacitor. Note that the pad 21 is disposed in a recess 26 formed in a surface of the insulating layer 121. The pad 25 is disposed in a recess 27 formed in a surface of the insulating layer 221.

The dielectric layer 23 can be made of an insulating member such as aluminum oxide (AlOₓ), zirconium oxide (ZrOₓ), hafnium oxide (HfOₓ), or titanium oxide (TiOₓ).

The first electrode 22 and the second electrode 24 can be made of metal such as titanium (Ti), tantalum (Ta), or tungsten (W) or a conductive member such as titanium nitride (TiN) or tantalum nitride (TaN). In addition, these members can also be used in combination.

In addition, when the pad 21 and the pad 25 are made of Cu, the first electrode 22 and the second electrode 24 can have a function as a barrier layer. Here, the barrier layer is disposed between the pad 21 or the like and the insulating layer 121 in order to prevent diffusion of the member constituting the pad 21 or the like into the insulating layer 121 or the like. Although not illustrated, a barrier layer is also disposed on the pad 21, the via plug 124, and the wiring 122.

The capacitive element 20 in the drawing can be disposed in a recess 28 formed in the pad 25. The recess 28 is formed in a partial region of a surface of the pad 25. The capacitive element 20 can be formed by sequentially stacking the second electrode 24, the dielectric layer 23, and the first electrode 22 in the recess 28. At this time, it is necessary to have a configuration in which the second electrode 24 is not disposed on a side wall of the recess 28 in a region in contact with the pad 21. This is to prevent a short circuit between the pad 21 and the second electrode 24. This can be performed by selective film formation in which the second electrode 24 is formed only on the surface of the pad 25 in the recess 28. Alternatively, it is also possible to remove the member of the second electrode 24 disposed on the side wall of the recess 28 after disposing the member of the second electrode 24 in the recess 28. The member of the second electrode 24 can be removed by anisotropic dry etching.

FIG. 3B is a plan view illustrating the configuration example of the capacitive element 20. The drawing is a diagram illustrating a configuration of the surface of the wiring region 220 as viewed from the semiconductor chip 100 side. Note that dotted lines in the drawing represent the pad 21 and the capacitive element connection pad 30.

As illustrated in the drawing, the second electrode 24 and the first electrode 22 are disposed at positions not overlapping in the recess 28. In addition, the capacitive element connection pad 30 is bonded and connected to a region different from a region of the pad 25 where the recess 28 is formed.

As described above, in the semiconductor element 10, the capacitive element 20 of the circuit to be accommodated can be disposed at an interface between the wiring region 120 and the wiring region 220. Since the capacitive element 20 can be disposed in a region used for a pad-to-pad connection, the area of the semiconductor chip 100 or the like can be reduced as compared with a case where the capacitive element 20 is disposed in the wiring region 120 or the like. In addition, the capacitive element 20 can also be disposed in a region of dummy connection of the pad-to-pad connection. Here, the dummy connection is a pad-to-pad connection by electrically isolated pads. This dummy connection is disposed to improve the bonding strength of the wiring regions 120 and 220, and the like. By disposing the capacitive element 20 in the region of the dummy connection of the pad-to-pad connection, the area of the semiconductor chip 100 or the like can be further reduced.

Note that the pad 25 in the drawing is an example of being configured in a circular shape in plan view, but the configuration of the pad 25 is not limited to this example. For example, the pad 25 configured in a rectangular shape in plan view can also be used. Similarly, the pad 21 and the capacitive element connection pad 30 can also be formed in a rectangular shape or the like in plan view.

### [Method for Manufacturing Semiconductor Element]

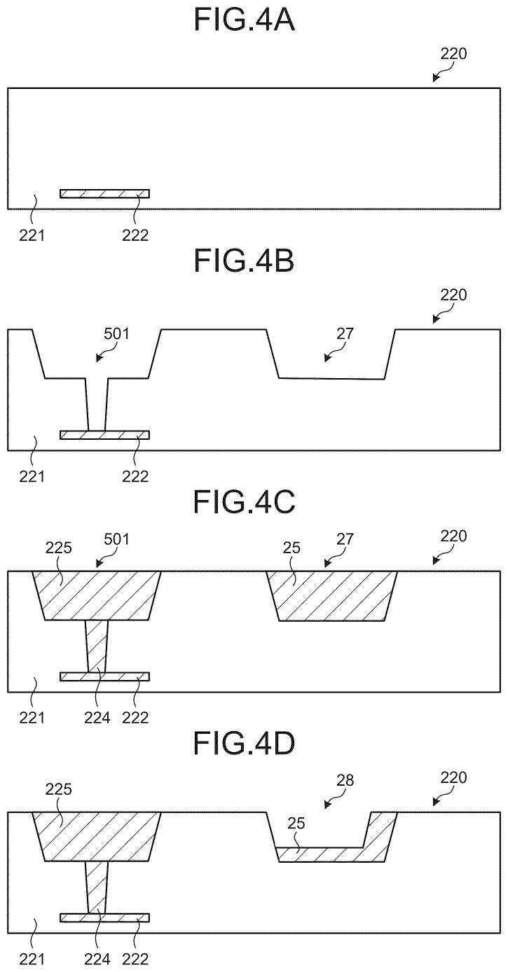

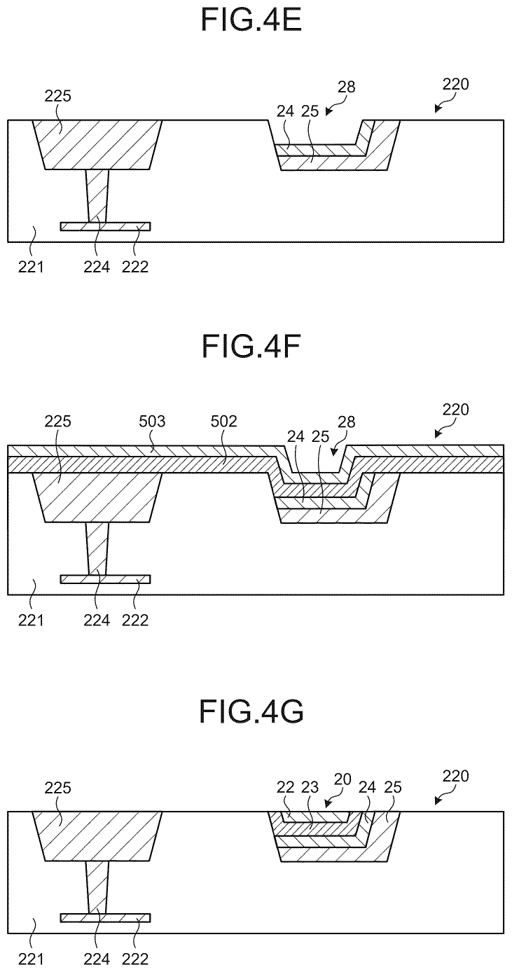

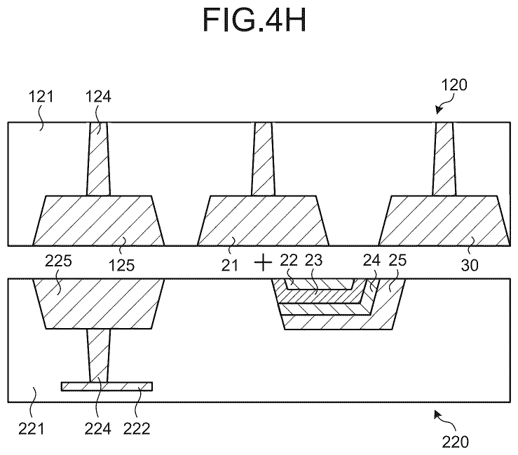

FIGS. 4A to 4H are diagrams illustrating an example of a method for manufacturing the semiconductor element according to the first embodiment of the present disclosure. The drawings are diagrams illustrating a manufacturing process of the semiconductor element 10. Note that in the drawings, illustration of the semiconductor substrates 110 and 210 is omitted.

First, the insulating layer 221 and the wiring 222 are disposed on the front-surface side of the semiconductor substrate 210 (FIG. 4A). Next, the recesses 27 and 501 described above are formed in the surface of the insulating layer 221 (FIG. 4B). The pad 225 and the via plug 224 are disposed in the recess 501. The recesses 27 and 501 can be formed by etching the insulating layer 221.

Next, a barrier layer (not illustrated) is disposed on wall surfaces of the recesses 27 and 501 to form the via plug 224, the pad 225, and the pad 25 (FIG. 4C). This can be performed by plating a Cu layer.

Next, the recess 28 is formed in the pad 25 (FIG. 4D). This can be performed by etching the pad 25.

Next, the second electrode 24 is disposed in the recess 28 (FIG. 4E). This can be performed by the selective film formation described above.

Next, a material film 502 constituting the dielectric layer 23 and a material film 503 constituting the first electrode 22 are sequentially stacked on the surface of the wiring region 220 including the recess 28 (FIG. 4F). Next, the surface of the wiring region 220 is ground to remove the material films 502 and 503 disposed in a region other than the recess 28 (FIG. 4G). The surface of the wiring region 220 can be ground by, for example, chemical mechanical polishing (CMP). Thus, the capacitive element 20 can be formed.

Next, the surface of the wiring region 120 of the semiconductor chip 100 is bonded to the surface of the wiring region 220 (FIG. 4H). This can be performed by performing plasma treatment on the surfaces of the wiring region 220 and the wiring region 120, aligning and overlapping the surfaces, and performing thermal pressure welding. The semiconductor element 10 can be manufactured by the above steps.

As described above, in the semiconductor element 10 of the first embodiment of the present disclosure, the capacitive element 20 is disposed on the pad 25 for connection between the semiconductor substrates. Since the capacitive element 20 is disposed by forming the recess 28 in a region having a larger area than the via plug 224 or the like, the capacitive element 20 can be easily manufactured.

### 2. SECOND EMBODIMENT

In the semiconductor element 10 of the first embodiment described above, the capacitive element 20 is disposed on the pad 25. On the other hand, a semiconductor element 10 of a second embodiment of the present disclosure is different from the first embodiment described above in that a capacitive element 20 is disposed on a pad 21.

### [Configuration of Capacitive Element]

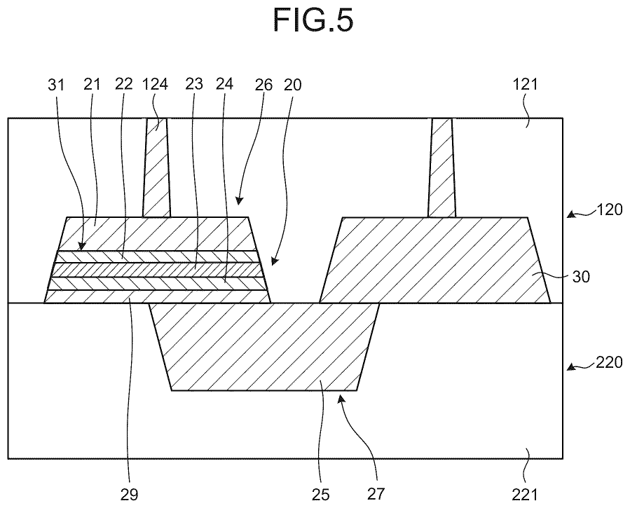

FIG. 5 is a diagram illustrating a configuration example of the capacitive element according to the second embodiment of the present disclosure. The drawing is a cross-sectional view illustrating a configuration example of the capacitive element 20, similarly to FIG. 3A. The capacitive element 20 in the drawing is different from the capacitive element 20 in FIG. 3A in that the capacitive element is disposed on the pad 21.

The capacitive element 20 in the drawing is disposed in a recess 31 formed in the pad 21. Specifically, the capacitive element 20 in the drawing is formed by sequentially stacking a first electrode 22, a dielectric layer 23, and a second electrode 24 in the recess 31.

In addition, a conductive film 29 can be stacked on the capacitive element 20. The conductive film 29 can be made of Cu, for example. By disposing the conductive film 29, the same material films as the pad 25 can be bonded at the time of pad-to-pad connection.

[Method for Manufacturing Semiconductor Element]

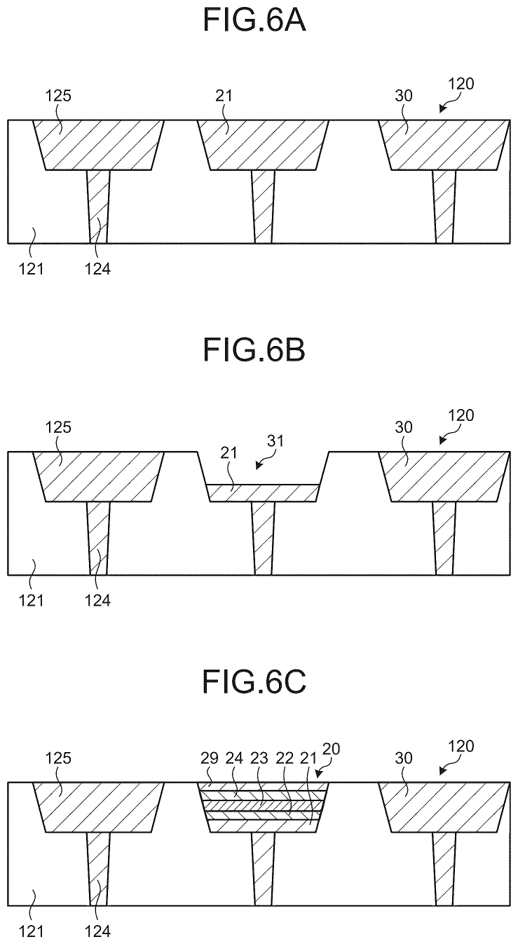

FIGS. 6A to 6C are diagrams illustrating an example of a method for manufacturing the semiconductor element according to the first embodiment of the present disclosure. The drawings are diagrams illustrating a manufacturing process of the semiconductor element 10. Note that illustration of semiconductor substrates 110 and 210 is omitted, similarly to FIGS. 4A to 4H.

First, an insulating layer 121, a wiring 122 (not illustrated), a via plug 124, pads 125 and 21, and a capacitive element connection pad 30 are disposed on a front-surface side of the semiconductor substrate 110 (FIG. 6A). Next, the recess 31 is formed in a surface of the pad 21 (FIG. 6B). Next, the first electrode 22, the dielectric layer 23, and the second electrode 24 are stacked in the recess 31 to form the capacitive element 20. Next, the conductive film 29 is formed. This can be performed by a plating method using the second electrode 24 as a seed layer. In addition, it can also be formed by physical vapor deposition (PVD) (FIG. 6C).

Next, the semiconductor element 10 can be manufactured by bonding a surface of a wiring region 220 of a semiconductor chip 200 to a surface of a wiring region 120.

Since the configuration of the semiconductor element 10 other than this is similar to the configuration of the semiconductor element 10 in the first embodiment of the present disclosure, the description thereof will be omitted.

As described above, in the semiconductor element 10 of the second embodiment of the present disclosure, the capacitive element 20 is disposed on the pad 21. Similarly to a case where the capacitive element 20 is disposed on the pad 25, the capacitive element 20 can be easily manufactured.

### 3. THIRD EMBODIMENT

In the semiconductor element 10 of the first embodiment described above, the capacitive element 20 is disposed on the pad 25. On the other hand, a semiconductor element 10 of a third embodiment of the present disclosure is connected to a pad 25. The present embodiment is different from the first embodiment described above in that a parasitic capacitance between a pad 21 and a capacitive element connection pad 30 is further used.

### [Configuration of Capacitive Element]

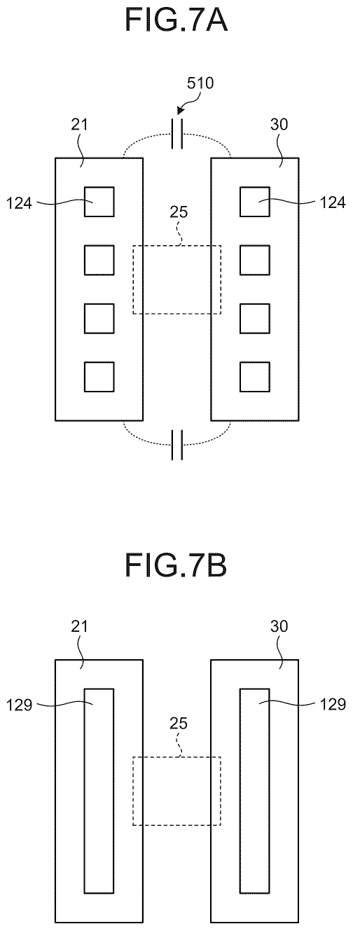

FIGS. 7A and 7B are diagrams illustrating configuration examples of a capacitive element according to the third embodiment of the present disclosure. The drawings are diagrams illustrating a configuration of the capacitive element 20 when viewed from a semiconductor substrate 110 side of a semiconductor chip 100. Broken lines in the drawings represent the pad 25.

The pad 21 and the capacitive element connection pad 30 in FIG. 7A are configured in a rectangular shape in plan view, and are disposed in a shape facing each other on long sides. Thus, a parasitic capacitance 510 having a relatively high capacitance is formed between the pad 21 and the capacitive element connection pad 30. Since the parasitic capacitance 510 is connected in parallel to the capacitive element 20, the capacitance of the capacitive element 20 can be increased.

FIG. 7B is a diagram illustrating an example in which a via plug 129 is disposed instead of a via plug 124. The via plug 129 is a via plug configured to have a rectangular cross-section.

### [Other Configurations of Capacitive Element]

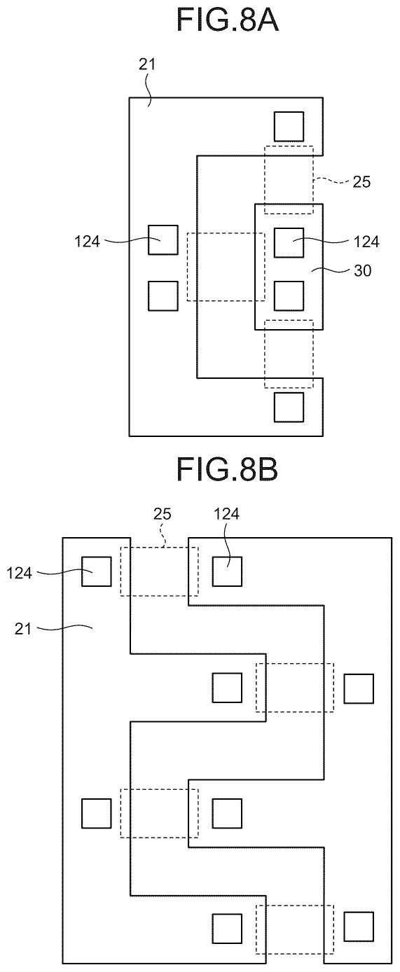

FIGS. 8A and 8B are diagrams illustrating other configuration examples of the capacitive element according to the third embodiment of the present disclosure. The drawings are diagrams illustrating examples of a case where surfaces of the pad 21 and the capacitive element connection pad 30 facing each other are further widened. In addition, the drawings illustrate an example in which a plurality of the pads 25 are disposed. The capacitive elements 20 (not illustrated) can be respectively disposed for these pads 25.

Since the configuration of the semiconductor element 10 other than this is similar to the configuration of the semiconductor element 10 in the first embodiment of the present disclosure, the description thereof will be omitted.

As described above, the semiconductor element 10 of the third embodiment of the present disclosure uses the pad 21 and the capacitive element connection pad 30 having the widened surfaces facing each other. Thus, the capacitance of the capacitive element 20 can be increased.

### 4. MODIFIED EXAMPLE

The semiconductor element 10 of the first embodiment described above uses the capacitive element connection pad 30, but other configurations can be adopted.

### [Configuration of Capacitive Element]

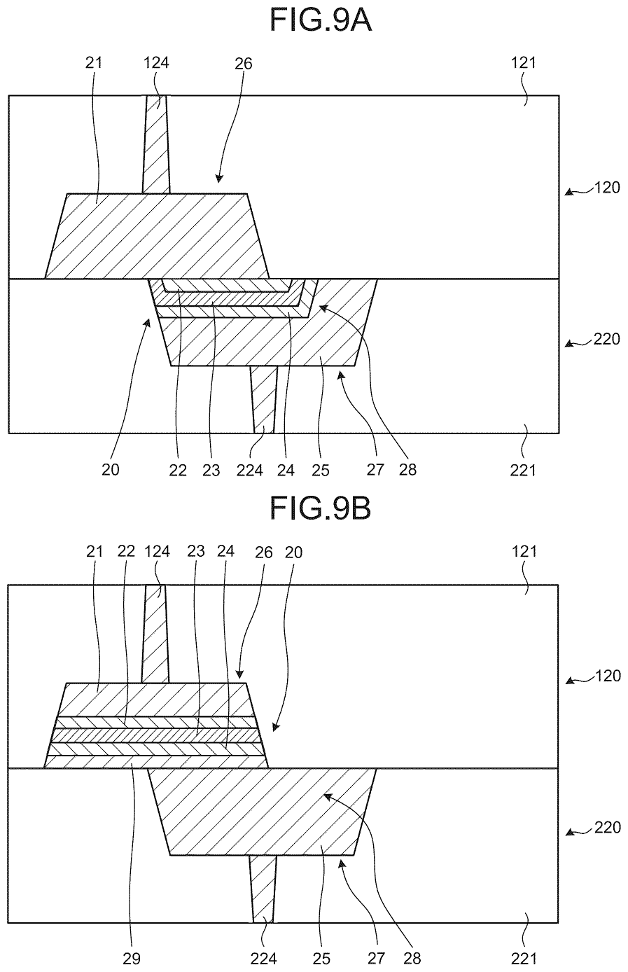

FIGS. 9A and 9B are diagrams illustrating configuration examples of capacitive elements according to modified examples of the embodiment of the present disclosure. The drawings illustrate examples of a case where the capacitive element connection pad 30 is omitted and the via plug 224 is connected to the pad 25. FIG. 9A illustrates an example of a case where the capacitive element 20 is disposed on the pad 25, and FIG. 9B illustrates an example of a case where the capacitive element 20 is disposed on the pad 21. In a case where the capacitive element 20 is connected between the electronic circuits disposed in the semiconductor substrates 110 and 210, it is possible to adopt a configuration in which the via plug 224 and the wiring 222 (not illustrated) are connected to the pad 25 and connected to the electronic circuit of the semiconductor substrate 210.

### 5. APPLICATION EXAMPLE

The semiconductor element 10 of the first embodiment described above can be applied to various products. For example, the technology according to the present disclosure may be applied to an event-based vision sensor (EVS). The EVS is a system that detects movement of a target object by detecting a change in luminance of an image of a subject. The EVS includes an imaging element having a plurality of pixels. The plurality of pixels detect that the absolute value of the amount of change in luminance of incident light exceeds a threshold as an address event. This event includes, for example, an on-event indicating that the amount of increase in luminance exceeds the threshold in the increasing direction and an off-event indicating that the amount of decrease in luminance falls below the threshold in the decreasing direction. Then, the imaging element generates a detection signal indicating a detection result of the event for each pixel. Each of the detection signals includes a detection signal indicating the presence or absence of the on-event and a detection signal indicating the presence or absence of the off-event.

### [Configuration of Imaging Element]

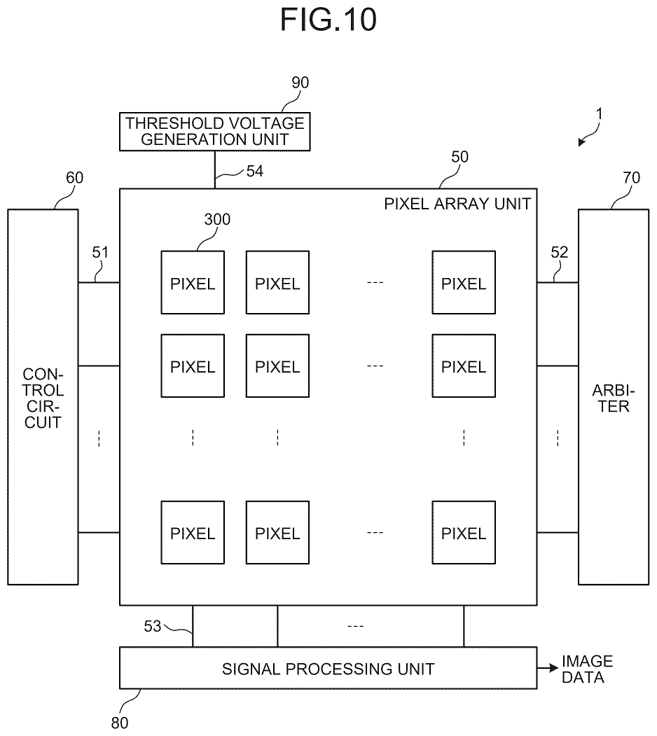

FIG. 10 is a block diagram illustrating a configuration example of an imaging element to which the technology according to the present disclosure can be applied. An imaging element 1 in the drawing constitutes an EVS system. The imaging element 1 includes a pixel array unit 50, a control circuit 60, an arbiter 70, a signal processing unit 80, and a threshold voltage generation unit 90.

The pixel array unit 50 is configured by arranging a plurality of pixels 300. The pixel array unit 50 in the drawing illustrates an example in which the pixels 300 are disposed in a two-dimensional matrix. The pixel 300 includes a photoelectric conversion unit that performs photoelectric conversion of incident light, and detects an event on the basis of the amount of change in photocurrent based on the photoelectric conversion.

The pixel 300 that has detected the event outputs a detection signal of the event to the control circuit 60 and the signal processing unit 80 to be described later. The control circuit 60 outputs a control signal to the pixel 300 that has output the detection signal, and resets the event detected in the pixel 300. In addition, the signal processing unit 80 performs predetermined signal processing on the detection signal.

Prior to the output of the detection signal, the pixel 300 transmits a request for requesting the arbiter 70 to be described later to output the detection signal. The arbiter 70 selects the pixel 300 that has transmitted the request and outputs a response to the request. This response permits the output of the detection signal.

The control circuit 60 is a circuit that controls resetting of a pixel address event in each pixel 300 of the pixel array unit 50. The control circuit 60 outputs a control signal for resetting a differentiating circuit 330 disposed in the pixel 300 to be described later. The pixel 300 and the control circuit 60 are connected by a signal line 51. The detection signal of the event from the pixel 300 and the control signal from the control circuit 60 are transmitted by the signal line 51.

The arbiter 70 selects the pixel 300 that has transmitted the request. As described above, the pixel 300 that has detected the address event outputs the detection signal to the control circuit 60 and the signal processing unit 80. It is necessary to exclusively supply the control signal to one pixel 300. This is to prevent collision at the time of outputting detection signals in the plurality of pixels 300. Therefore, the arbiter 70 arbitrates the plurality of pixels 300 in which the pixel address events have been detected. Specifically, the arbiter 70 selects one of the pixels 300 that sent the request, and returns a response to the selected pixel 300. This response represents a result of the selection. The pixel 300 and the arbiter 70 are connected by a signal line 52. The request from the pixel 300 and the response from the arbiter 70 are transmitted by the signal line 52.

When requests are transmitted from the plurality of pixels 300, the arbiter 70 can select the pixels 300 in the order in which the requests are transmitted. At this time, the arbiter 70 can preferentially select a specific pixel 300. For example, the arbiter 70 can preferentially select the pixel 300 that has transmitted a request to which a high priority to be described later is set.

The signal processing unit 80 performs predetermined signal processing on the detection signal from the pixel 300. For example, the signal processing unit 80 can arrange such detection signals as image signals in a two-dimensional matrix and generate image data having 2-bit information for each pixel 300. In addition, the signal processing unit 80 can perform signal processing such as image recognition processing on the generated image data. The pixel 300 and the signal processing unit 80 are connected by a signal line 53. The detection signal from the pixel 300 is transmitted by the signal line 53.

The threshold voltage generation unit 90 generates a threshold voltage that is a voltage corresponding to the threshold described above. The threshold voltage generation unit 90 supplies the generated threshold voltage to the pixel 300. The threshold voltage is transmitted by a signal line 54.

### [Configuration of Pixel]

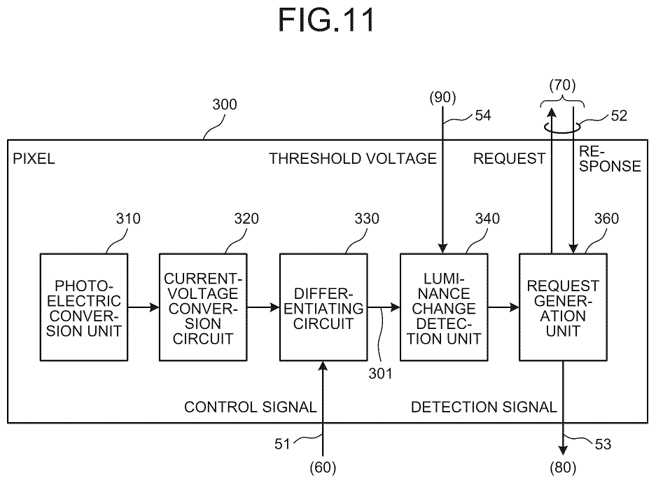

FIG. 11 is a diagram illustrating a configuration example of a pixel to which the technology according to the present disclosure can be applied. The drawing is a diagram illustrating a configuration example of the pixel 300. The pixel 300 in the drawing includes a photoelectric conversion unit 310, a current-voltage conversion circuit 320, the differentiating circuit 330, a luminance change detection unit 340, and a request generation unit 360.

The photoelectric conversion unit 310 performs photoelectric conversion of incident light. The photoelectric conversion unit 310 can include a photodiode. By this photoelectric conversion, a charge corresponding to the luminance of the incident light is generated. By applying a voltage to the photoelectric conversion unit 310, a photocurrent that is a current corresponding to the generated charge can be supplied to an external circuit.

The current-voltage conversion circuit 320 converts the photocurrent from the photoelectric conversion unit 310 into a voltage signal. In addition, in this conversion, the current-voltage conversion circuit 320 performs logarithmic compression of the voltage signal. The converted voltage signal is output to the differentiating circuit 330. Details of the configuration of the current-voltage conversion circuit 320 will be described later.

The differentiating circuit 330 extracts a change in the voltage signal output from the current-voltage conversion circuit 320 and integrates the change to generate a signal corresponding to the amount of change in the voltage signal. This signal corresponds to a signal corresponding to a change in luminance of the incident light. This signal is referred to as an optical signal. The differentiating circuit 330 outputs the generated optical signal to the luminance change detection unit 340. This optical signal is transmitted by a signal line 301.

In addition, the control signal is input from the control circuit 60 to the differentiating circuit 330. The control signal is a signal for resetting a circuit that detects the amount of change in the voltage signal described above. Details of the configuration of the differentiating circuit 330 will be described later.

The luminance change detection unit 340 detects a change in luminance of the incident light. The luminance change detection unit 340 in the drawing detects a change in the optical signal output from the differentiating circuit 330 based on the threshold voltage supplied from the threshold voltage generation unit 90. The detection result is output to the request generation unit 360.

The request generation unit 360 generates a request for requesting transfer of the detection result of the change in luminance in the luminance change detection unit 340, and outputs the request to the arbiter 70. In addition, when a response to the request is output from the arbiter 70, the request generation unit 360 outputs a detection signal of the change in luminance to the signal processing unit 80 and the control circuit 60.

### [Configurations of Current-Voltage Conversion Circuit and Differentiating Circuit]

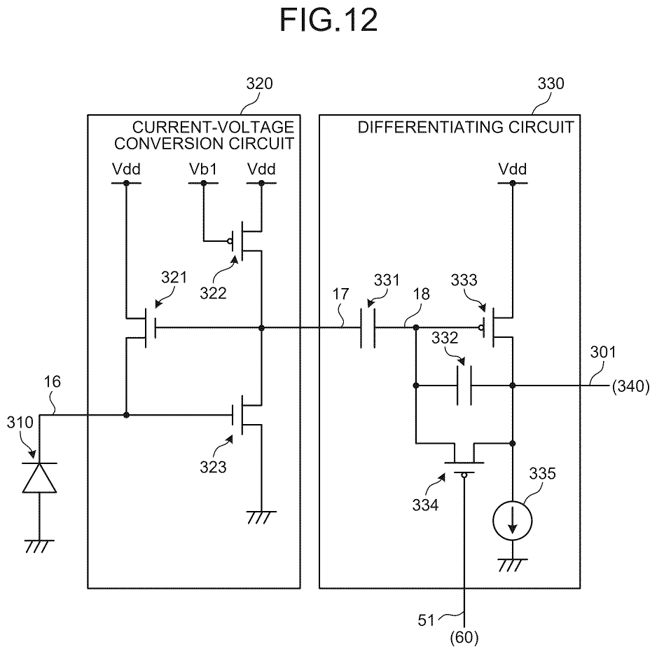

FIG. 12 is a diagram illustrating a configuration example of a current-voltage conversion circuit and a differentiating circuit to which the technology according to the present disclosure can be applied. The drawing is a circuit diagram illustrating a configuration example of the current-voltage conversion circuit 320 and the differentiating circuit 330. Note that the photoelectric conversion unit 310 is further illustrated in the drawing.

The current-voltage conversion circuit 320 in the drawing includes MOS transistors 321 to 323. The reference sign Vdd in the drawing represents a power supply line Vdd that supplies power. The reference sign Vb1 represents a signal line Vb1 that supplies a bias voltage. As the MOS transistors 321 and 323, n-channel MOS transistors can be used. As the MOS transistor 322, a p-channel MOS transistor can be used.

An anode of the photoelectric conversion unit 310 is grounded, and a cathode is connected to an input of the current-voltage conversion circuit 320 via the signal line 16. In the current-voltage conversion circuit 320, the signal line 16 is connected to a source of the MOS transistor 321 and a gate of the MOS transistor 323. Drains of the MOS transistor 321 and the MOS transistor 322 are connected to the power supply line Vdd, and a gate of the MOS transistor 322 is connected to the signal line Vb1. A source of the MOS transistor 323 is grounded, and a drain is connected to a gate of the MOS transistor 321, the drain of the MOS transistor 322, and the signal line 17 which is an output signal line of the current-voltage conversion circuit 320. One end of a capacitor of the differentiating circuit 330 is connected to the signal line 17.

The MOS transistor 321 is a MOS transistor that supplies a current to the photoelectric conversion unit 310. A sink current (photocurrent) corresponding to incident light flows through the photoelectric conversion unit 310. The MOS transistor 321 supplies the sink current. At this time, the gate of the MOS transistor 321 is driven by an output voltage of the MOS transistor 323 to be described later, and outputs a source current equal to the sink current of the photoelectric conversion unit 310. Since a gate-source voltage Vgs of the MOS transistor is a voltage corresponding to the source current, a source voltage of the MOS transistor 321 is a voltage corresponding to the current of the photoelectric conversion unit 310. Thus, the photocurrent of the photoelectric conversion unit 310 is converted into a voltage signal.

The MOS transistor 323 is a MOS transistor that amplifies the source voltage of the MOS transistor 321. In addition, the MOS transistor 322 constitutes a constant current load of the MOS transistor 323. An amplified voltage signal is output to the drain of the MOS transistor 323. This voltage signal is output to the signal line 17 and fed back to the gate of the MOS transistor 321. When Vgs of the MOS transistor 321 is equal to or lower than a threshold voltage, the source current changes in an exponential manner with respect to a change in Vgs. Therefore, the output voltage of the MOS transistor 323 fed back to the gate of the MOS transistor 321 is a voltage signal obtained by logarithmically compressing the photocurrent of the photoelectric conversion unit 310 equal to the source current of the MOS transistor 321.

### [Configuration of Differentiating Circuit]

The differentiating circuit 330 in the drawing includes capacitive elements 331 and 332, MOS transistors 333 and 334, and a constant current circuit 335. As the MOS transistors 333 and 334, p-channel MOS transistors can be used.

As described above, the signal line 17 is connected to one end of the capacitive element 331, and the other end of the capacitive element 331 is connected to a gate of the MOS transistor 333, a drain of the MOS transistor 334, and one end of the capacitive element 332 via the signal line 18. The other end of the capacitive element 332 is connected to a drain of the MOS transistor 333, the drain of the MOS transistor 334, a sink-side terminal of the constant current circuit 335, and the signal line 301. A source of the MOS transistor 333 is connected to the power supply line Vdd, and a gate of the MOS transistor 334 is connected to the signal line 51. The sink-side terminal of the constant current circuit 335 is grounded.

The capacitive element 331 corresponds to a coupling capacitor. The capacitive element 331 blocks a DC component of the output voltage of the current-voltage conversion circuit 320 and allows only an AC component to pass therethrough. In addition, a current based on a change in the output voltage of the current-voltage conversion circuit 320 is supplied to the gate of the MOS transistor 333 via the capacitive element 331. The AC component of the output voltage of the current-voltage conversion circuit 320 corresponds to a change in photocurrent. The MOS transistor 333 and the constant current circuit 335 constitute an inverting amplifier circuit. Note that the MOS transistor 522 constitutes a constant current load. A change in the output voltage of the current-voltage conversion circuit 320 is input to the gate of the MOS transistor 333 via the capacitive element 331, is inverted and amplified by the MOS transistor 333, and is output to the drain. Therefore, a current based on the change in the output voltage of the current-voltage conversion circuit 320 flows through the capacitive element 332, and the capacitive element 332 is charged and discharged. That is, the change in the output voltage of the current-voltage conversion circuit 320 is integrated (integrated). An optical signal that is a signal corresponding to the amount of change in the voltage signal output by the current-voltage conversion circuit 320 is output to the signal line 301.

The MOS transistor 334 resets the differentiating circuit 330. By conducting the MOS transistor 334, both ends of the capacitive element 332 are short-circuited. The integrated change in the output voltage of the current-voltage conversion circuit 320 is discharged and reset. By this reset, the output voltage of the differentiating circuit 330 becomes, for example, a voltage at a midpoint between the power supply line Vdd and a ground line.

### [Configuration of Pixel Array Unit]

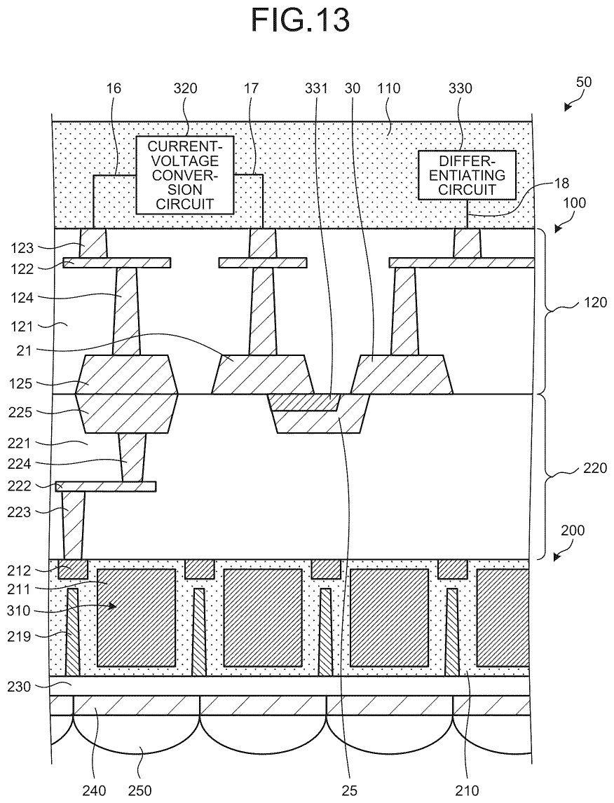

FIG. 13 is a diagram illustrating a configuration example of a pixel array unit to which the technology according to the present disclosure can be applied. The drawing is a cross-sectional view illustrating a configuration example of the pixel array unit 50. The pixel array unit 50 can have a configuration similar to that of the semiconductor element 10 in FIG. 2.

The photoelectric conversion unit 310 is disposed in the semiconductor substrate 210. A semiconductor region 211 disposed in the semiconductor substrate 210 constitutes the photoelectric conversion unit 310. Specifically, a photodiode including a pn junction formed between the semiconductor region 211 and a surrounding well region corresponds to the photoelectric conversion unit 310. A charge generated by the photoelectric conversion unit 310 is transferred to a semiconductor region 212 by a transfer transistor (not illustrated). The contact plug 223 constituting the signal line 16 is connected to the semiconductor region 212.

A separation region 219 is disposed between the photoelectric conversion units 310 of the semiconductor substrate 110. In addition, a protective film 230, a color filter 240, and an on-chip lens 250 are sequentially disposed on a back-surface side of the semiconductor substrate 110.

The current-voltage conversion circuit 320 and the differentiating circuit 330 are disposed in the semiconductor substrate 110. In addition, the capacitive element 331 is disposed on the pad 25 similarly to the capacitive element 20 in FIG. 2.

By disposing the capacitive element 331 on the pad 25, the EVS can be downsized.

Note that the configuration of the second embodiment of the present disclosure can be applied to other embodiments. Specifically, the conductive film 29 in FIG. 5 can be applied to the capacitive element 20 in FIG. 3A.

Note that the effects described in the present specification are merely examples and are not limited, and other effects may be provided.

Note that the present technology can also have the following configurations.

(1)

A semiconductor element comprising:
a first semiconductor substrate;
a second semiconductor substrate;
a first wiring region disposed adjacent to the first semiconductor substrate;
a second wiring region disposed adjacent to the second semiconductor substrate and having a surface bonded to a surface of the first wiring region;
a first pad embedded in the surface of the first wiring region;
a second pad embedded in the surface of the second wiring region and disposed at a position overlapping the first pad in plan view when the surface of the first wiring region and the surface of the second wiring region are bonded;
a capacitive element configured by sequentially stacking a first electrode, a dielectric layer, and a second electrode disposed on any one of the first pad and the second pad; and
a capacitive element connection pad that is a pad embedded in the surface of the first wiring region and connected to the second pad when the surface of the first wiring region and the surface of the second wiring region are bonded.
   (2)

The semiconductor element according to the above (1), further comprising a conductive film stacked on the capacitive element.

(3)

The semiconductor element according to the above (1) or (2), wherein the capacitive element is disposed in a recess formed in a surface of either the first pad or the second pad.

(4)

The semiconductor element according to the above (1), wherein
the capacitive element is disposed in a recess formed in a surface of the second pad, and
the capacitive element connection pad is connected to a region different from the recess in the surface of the second pad.
   (5)

The semiconductor element according to any one of the above (1) to (4), wherein the first wiring region includes a wiring connected to the first pad and a wiring connected to the capacitive element connection pad.

(6)

A semiconductor apparatus comprising:
a first semiconductor substrate;
a second semiconductor substrate;
a first wiring region disposed adjacent to the first semiconductor substrate;
a second wiring region disposed adjacent to the second semiconductor substrate and having a surface bonded to a surface of the first wiring region;
a first pad embedded in the surface of the first wiring region;
a second pad embedded in the surface of the second wiring region and disposed at a position overlapping the first pad in plan view when the surface of the first wiring region and the surface of the second wiring region are bonded;
a capacitive element configured by sequentially stacking a first electrode, a dielectric layer, and a second electrode disposed on any one of the first pad and the second pad;
a capacitive element connection pad that is a pad embedded in the surface of the first wiring region and connected to the second pad when the surface of the first wiring region and the surface of the second wiring region are bonded;
a first electronic circuit connected to the first pad via a wiring disposed in the first wiring region; and
a second electronic circuit connected to the capacitive element connection pad via a wiring disposed in the first wiring region.

### REFERENCE SIGNS LIST

1 IMAGING ELEMENT
10 SEMICONDUCTOR ELEMENT
11 to 13 ELECTRONIC CIRCUIT
20, 331 CAPACITIVE ELEMENT
21, 25, 125, 225 PAD
22 FIRST ELECTRODE
23 DIELECTRIC LAYER
24 SECOND ELECTRODE
26 to 28, 31 RECESS
29 CONDUCTIVE FILM
30 CAPACITIVE ELEMENT CONNECTION PAD
50 PIXEL ARRAY UNIT
100, 200 SEMICONDUCTOR CHIP
110, 210 SEMICONDUCTOR SUBSTRATE
120, 220 WIRING REGION
310 PHOTOELECTRIC CONVERSION UNIT
320 CURRENT-VOLTAGE CONVERSION CIRCUIT
330 DIFFERENTIATING CIRCUIT

What is claimed is:

1. A semiconductor element, comprising:
a first semiconductor substrate;
a second semiconductor substrate;
a first wiring region disposed adjacent to the first semiconductor substrate;
a second wiring region disposed adjacent to the second semiconductor substrate and having a surface bonded to a surface of the first wiring region;
a first pad embedded in the surface of the first wiring region;
a second pad embedded in the surface of the second wiring region and disposed at a position overlapping the first pad in plan view when the surface of the first wiring region and the surface of the second wiring region are bonded;
a capacitive element configured by sequentially stacking a first electrode, a dielectric layer, and a second electrode disposed on any one of the first pad and the second pad; and
a capacitive element connection pad that is a pad embedded in the surface of the first wiring region and connected to the second pad when the surface of the first wiring region and the surface of the second wiring region are bonded.

2. The semiconductor element according to claim 1, further comprising a conductive film stacked on the capacitive element.

3. The semiconductor element according to claim 1, wherein the capacitive element is disposed in a recess formed in a surface of either the first pad or the second pad.

4. The semiconductor element according to claim 1, wherein
the capacitive element is disposed in a recess formed in a surface of the second pad, and
the capacitive element connection pad is connected to a region different from the recess in the surface of the second pad.

5. The semiconductor element according to claim 1, wherein the first wiring region includes a wiring connected to the first pad and a wiring connected to the capacitive element connection pad.

6. A semiconductor apparatus, comprising:
a first semiconductor substrate;
a second semiconductor substrate;
a first wiring region disposed adjacent to the first semiconductor substrate;
a second wiring region disposed adjacent to the second semiconductor substrate and having a surface bonded to a surface of the first wiring region;
a first pad embedded in the surface of the first wiring region;
a second pad embedded in the surface of the second wiring region and disposed at a position overlapping the first pad in plan view when the surface of the first wiring region and the surface of the second wiring region are bonded;
a capacitive element configured by sequentially stacking a first electrode, a dielectric layer, and a second electrode disposed on any one of the first pad and the second pad;
a capacitive element connection pad that is a pad embedded in the surface of the first wiring region and connected to the second pad when the surface of the first wiring region and the surface of the second wiring region are bonded;
a first electronic circuit connected to the first pad via a wiring disposed in the first wiring region; and
a second electronic circuit connected to the capacitive element connection pad via a wiring disposed in the first wiring region.
